(19) United States
(12) Patent Application Publication
(10) Pub. No.: US 2009/0095994 A1
(43) Pub. Date: Apr. 16, 2009

(54) SEMICONDUCTOR DEVICE AND METHOD OF MANUFACTURING THE SAME

(75) Inventors: Hiroyuki Kanaya, Yokohama-shi (JP); Yoshinori Kumura, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/250,888

(22) Filed: Oct. 14, 2008

(30) Foreign Application Priority Data
Oct. 15, 2007 (JP) 2007-267441

(51) Int. Cl. H01L 27/108; H01L 21/02; H01L 21/44

(52) U.S. Cl. 257/295; 257/296; 438/3; 438/672; 257/E27.006; 257/E27.014; 257/E21.409

(57) ABSTRACT

A semiconductor device comprises a substrate; an insulating layer formed over the substrate; a contact hole formed through the insulating layer; a plurality of first plug electrodes each formed inside the contact hole to the surface of the insulating layer; a capacitor layer formed on the first plug electrode in a first region; and a second plug electrode formed on the first plug electrode in a second region different from the first region. The capacitor layer includes a lower electrode, a ferroelectric film, and an upper electrode stacked in turn. The first plug electrode includes a plug conduction layer formed from the surface of the substrate, and a plug barrier layer formed from above the plug conduction layer up to an upper surface of the insulating layer, the plug barrier layer having a higher etching selection ratio than the lower electrode.

### CROSS-REFERENCE TO RELATED APPLICATION

This application is based on and claims the benefit of priority from prior Japanese Patent Application No. 2007-267441, filed on Oct. 15, 2007, the entire contents of which are incorporated herein by reference.

### BACKGROUND OF THE INVENTION

1. Field of the Invention

The present invention relates to a semiconductor device such as a ferroelectric memory (FeRAM) and method of manufacturing the same.

2. Description of the Related Art

Memory devices including ferroelectric capacitors used as storage media (ferroelectric memory: FeRAM) have been developed and brought into practical use (Patent Document 1: JP-2002-25247A). The ferroelectric memory is nonvolatile and has excellent characteristics. For example, the stored content is not lost after power off, and high-speed write/read can be executed because the inversion speed of spontaneous polarization is fast if the film thickness is sufficiently thin. The ferroelectric memory is suitable for achievement of mass storage because one-bit memory cell can be configured with one transistor and one ferroelectric capacitor.

In recent years, the above-described ferroelectric memory has been further given a higher capacity and a finer pattern progressively. This results in a need for development in technologies of fine pattering of COP (Capacitor On Plug) and ferroelectric capacitors. In the current state, fine pattering of capacitors inevitably requires a step of high-temperature etching (above 300° C.) to rise the capacitor taper angle. Such the step, however, lowers the yield of the ferroelectric memory due to the problem shown below.

The problem in the current state is described below. In production of the ferroelectric memory, after forming a switching transistor and a first plug electrode (tungsten plug) connected to a diffused layer thereof, a barrier layer (TiAlN film) and a capacitor layer are formed in a portion on the first plug electrode. The capacitor layer includes a lower electrode (Ir), a ferroelectric film (Pb(ZrₓTᵢ₋ₓ)O₃), and an upper electrode (IrO₂) from below. A hard mask (such as SiO₂) is formed over the capacitor layer and used in etching to remove the lower electrode, the ferroelectric film and the upper electrode from a region in which the hard mask is not formed. In this case, an etching executed at a high temperature (high-temperature etching) causes side-etching of the lower electrode and remarkable over-etching of the upper portion of the first plug electrode in the vicinity of the capacitor layer. Thereafter, a hydrogen protection film (Al₂O₃ film) and an interlayer insulator are deposited, and planarized, followed by contact processing the upper portion of the over-etched first plug electrode. Also in this step, the upper portion of the first plug electrode in the vicinity of the capacitor layer is over-etched.

As described above, in the process steps of the state of art, the first plug electrode in the external region is over-etched when the memory cell region for use in formation of memory cells and the external region other than the memory cell region are formed at the same time. In addition, the gate electrode beneath the first plug electrode in the external region may also be over-etched possibly. Therefore, it is required to execute the process steps for the memory cell region and the process steps for the external region separately and independently.

In the process steps of the state of art, the side-etching of the barrier layer deteriorates the coverage of the hydrogen protection film and lowers the capacitor characteristic of the ferroelectric memory.

### SUMMARY OF THE INVENTION

In one aspect the present invention provides a semiconductor device, comprising: a substrate; an insulating layer formed over the substrate; a contact hole formed through the insulating layer; a plurality of first plug electrodes each formed inside the contact hole up to the surface of the insulating layer; a capacitor layer formed on the first plug electrode in a first region; and a second plug electrode formed on the first plug electrode in a second region different from the first region, the capacitor layer including a lower electrode, a ferroelectric film, and an upper electrode stacked in turn, the first plug electrode including a plug conduction layer formed from the surface of the substrate, and a plug barrier layer formed from above the plug conduction layer up to an upper surface of the insulating layer, the plug barrier layer having a higher etching selection ratio than the lower electrode.

In one aspect the present invention provides a semiconductor device, comprising: a substrate; an insulating layer formed over the substrate; a contact hole formed through the insulating layer; a plurality of first plug electrodes each formed inside the contact hole up to the surface of the insulating layer; a capacitor layer formed on the first plug electrode in a first region; and a second plug electrode formed on the first plug electrode in a second region different from the first region, the capacitor layer including a lower electrode, a ferroelectric film, and an upper electrode stacked in turn, the first plug electrode including a plug barrier layer formed from the surface of the substrate up to an upper surface of the insulating layer, the plug barrier layer having a higher etching selection ratio than the lower electrode.

In one aspect the present invention provides a method of manufacturing semiconductor devices, comprising: depositing an insulating layer over a substrate; forming a contact hole through the insulating layer; forming a first plug electrode inside the contact hole up to the surface of the insulating layer; forming a capacitor layer on the first plug electrode in a first region by stacking a lower electrode, a ferroelectric film, and an upper electrode; forming a second plug electrode on the first plug electrode in a second region different from the first region, the method further comprising; for forming the first plug electrode, forming a plug conduction layer from the surface of the substrate, and forming a barrier layer from above the plug conduction layer up to an upper surface of the insulating layer, the barrier layer having a higher etching selection ratio than the lower electrode, thereby configuring the first plug electrode with the plug conduction layer and the barrier layer.

### BRIEF DESCRIPTION OF THE DRAWINGS

FIG. 1 is a circuit diagram showing a configuration of a semiconductor device 100 according to a first embodiment of the present invention.

FIG. 2A shows operation of the semiconductor device 100 according to the first embodiment of the present invention.

FIG. 2B shows the hysteresis characteristic of a ferroelectric capacitor in the semiconductor device 100 according to the first embodiment of the present invention.

FIG. 2C shows operation of the semiconductor device 100 according to the first embodiment of the present invention.

FIG. 2D shows the hysteresis characteristic of a ferroelectric capacitor in the semiconductor device 100 according to the first embodiment of the present invention.

FIG. 3 is a brief cross-sectional view of the major part of a memory cell block MCB0 in a memory cell array 1a in the semiconductor device 100 according to the first embodiment of the present invention.

FIG. 4A is across-sectional view of a memory cell MC region in the semiconductor device 100 according to the first embodiment of the present invention.

FIG. 4B is a cross-sectional view of an external region in the semiconductor device 100 according to the first embodiment of the present invention.

FIG. 5A is a cross-sectional view of the memory cell MC region in the semiconductor device 100 according to the first embodiment of the present invention showing the first process steps.

FIG. 5B is a cross-sectional view of the external region in the semiconductor device 100 according to the first embodiment of the present invention showing the first process steps.

FIG. 6A is a cross-sectional view of the memory cell MC region in the semiconductor device 100 according to the first embodiment of the present invention showing the first process steps.

FIG. 6B is a cross-sectional view of the external region in the semiconductor device 100 according to the first embodiment of the present invention showing the first process steps.

FIG. 7A is a cross-sectional view of the memory cell MC region in the semiconductor device 100 according to the first embodiment of the present invention showing the first process steps.

FIG. 7B is a cross-sectional view of the external region in the semiconductor device 100 according to the first embodiment of the present invention showing the first process steps.

FIG. 8A is a cross-sectional view of the memory cell MC region in the semiconductor device 100 according to the first embodiment of the present invention showing the first process steps.

FIG. 8B is a cross-sectional view of the external region in the semiconductor device 100 according to the first embodiment of the present invention showing the first process steps.

FIG. 9A is a cross-sectional view of the memory cell MC region in the semiconductor device 100 according to the first embodiment of the present invention showing the first process steps.

FIG. 9B is a cross-sectional view of the external region in the semiconductor device 100 according to the first embodiment of the present invention showing the first process steps.

FIG. 10A is a cross-sectional view of the memory cell MC region in the semiconductor device 100 according to the first embodiment of the present invention showing the first process steps.

FIG. 10B is a cross-sectional view of the external region in the semiconductor device 100 according to the first embodiment of the present invention showing the first process steps.

FIG. 11A is a cross-sectional view of the memory cell MC region in the semiconductor device 100 according to the first embodiment of the present invention showing the first process steps.

FIG. 11B is a cross-sectional view of the external region in the semiconductor device 100 according to the first embodiment of the present invention showing the first process steps.

FIG. 12A is a cross-sectional view of the memory cell MC region in the semiconductor device 100 according to the first embodiment of the present invention showing the first process steps.

FIG. 12B is a cross-sectional view of the external region in the semiconductor device 100 according to the first embodiment of the present invention showing the first process steps.

FIG. 13A is a cross-sectional view of the memory cell MC region in the semiconductor device 100 according to the first embodiment of the present invention showing the first process steps.

FIG. 13B is a cross-sectional view of the external region in the semiconductor device 100 according to the first embodiment of the present invention showing the first process steps.

FIG. 14A is a cross-sectional view of the memory cell MC region in the semiconductor device 100 according to the first embodiment of the present invention showing the first process steps.

FIG. 14B is a cross-sectional view of the external region in the semiconductor device 100 according to the first embodiment of the present invention showing the first process steps.

FIG. 15A is a cross-sectional view of the memory cell MC region in the semiconductor device 100 according to the first embodiment of the present invention showing the first process steps.

FIG. 15B is a cross-sectional view of the external region in the semiconductor device 100 according to the first embodiment of the present invention showing the first process steps.

FIG. 16A is a cross-sectional view of the memory cell MC region in the semiconductor device 100 according to the first embodiment of the present invention showing the first process steps.

FIG. 16B is a cross-sectional view of the external region in the semiconductor device 100 according to the first embodiment of the present invention showing the first process steps.

FIG. 17A is a cross-sectional view of the memory cell MC region in the semiconductor device 100 according to the first embodiment of the present invention showing the second process steps.

FIG. 17B is a cross-sectional view of the external region in the semiconductor device 100 according to the first embodiment of the present invention showing the second process steps.

FIG. 18A is a cross-sectional view of the memory cell MC region in the semiconductor device 100 according to the first embodiment of the present invention showing the second process steps.

FIG. 18B is a cross-sectional view of the external region in the semiconductor device 100 according to the first embodiment of the present invention showing the second process steps.

FIG. 19A is a cross-sectional view of the memory cell MC region in the semiconductor device 100 according to the first embodiment of the present invention showing the second process steps.

FIG. 19B is a cross-sectional view of the external region in the semiconductor device 100 according to the first embodiment of the present invention showing the second process steps.

FIG. 20A is a cross-sectional view of the memory cell MC region in the semiconductor device 100 according to the first embodiment of the present invention showing the second process steps.

FIG. 20B is a cross-sectional view of the external region in the semiconductor device 100 according to the first embodiment of the present invention showing the second process steps.

FIG. 21A is a cross-sectional view of the memory cell MC region in the semiconductor device 100 according to the first embodiment of the present invention showing the second process steps.

FIG. 21B is a cross-sectional view of the external region in the semiconductor device 100 according to the first embodiment of the present invention showing the second process steps.

FIG. 22A is a cross-sectional view of a memory cell MC region in a semiconductor device 100 according to a second embodiment of the present invention.

FIG. 22B is a cross-sectional view of an external region in the semiconductor device 100 according to the second embodiment of the present invention.

FIG. 23A is a cross-sectional view of the memory cell MC region in the semiconductor device 100 according to the second embodiment of the present invention showing the process steps.

FIG. 23B is a cross-sectional view of the external region in the semiconductor device 100 according to the second embodiment of the present invention showing the process steps.

FIG. 24A is a cross-sectional view of the memory cell MC region in the semiconductor device 100 according to the second embodiment of the present invention showing the process steps.

FIG. 24B is a cross-sectional view of the external region in the semiconductor device 100 according to the second embodiment of the present invention showing the process steps.

FIG. 25 is a cross-sectional view of the memory cell MC region in the semiconductor device according to the first embodiment of the present invention.

### DETAILED DESCRIPTION OF THE EMBODIMENTS

For a semiconductor device and method of manufacturing the same according to the present invention, one embodiment will now be described with reference to the drawings.

### First Embodiment

(Circuitry of Semiconductor Device 100 according to First Embodiment)

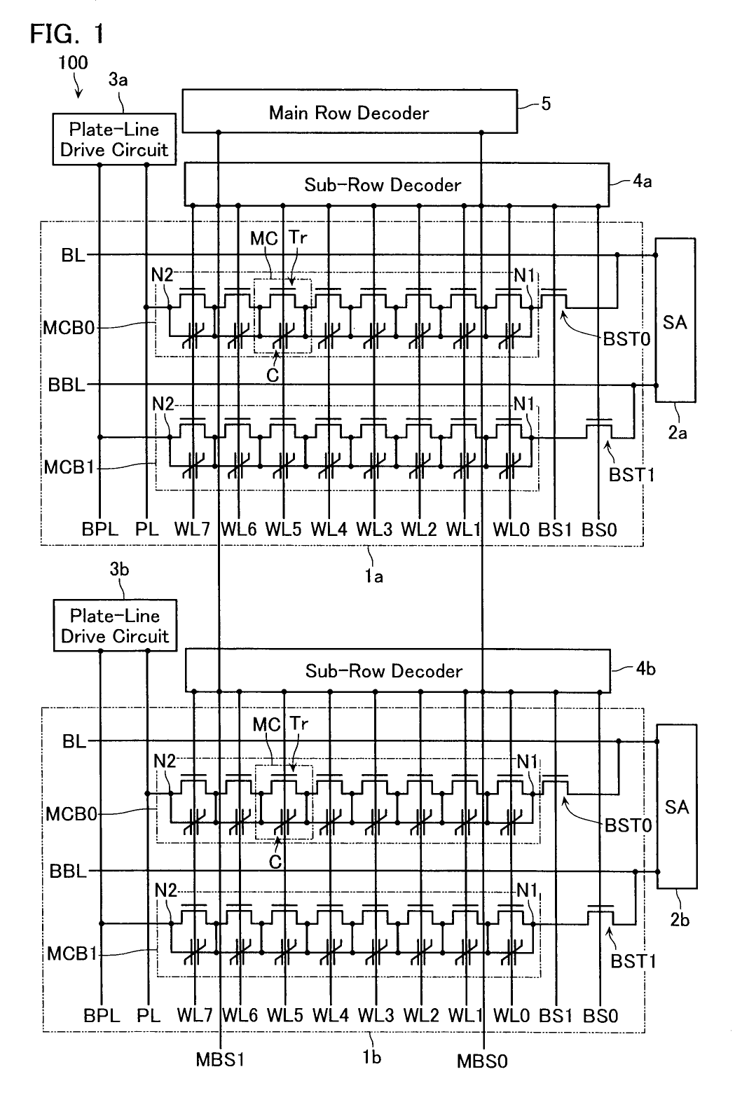

Referring first to FIG. 1, circuitry of a semiconductor device according to a first embodiment of the present invention is described. FIG. 1 is a circuit diagram showing a configuration of the semiconductor device 100 according to the first embodiment. As shown in FIG. 1, the semiconductor device 100 comprises memory cell arrays 1a, 1b for storing data, sense amplifier circuits 2a, 2b for sensing/amplifying read data, plate-line drive circuits 3a, 3b, sub-row decoder circuits 4a, 4b, and a main row decoder circuit 5.

The memory cell arrays 1a, 1b each comprise memory cells MC each including a ferroelectric capacitor C and a transistor Tr. In the memory cell MC, the ferroelectric capacitor C and the transistor Tr are connected in parallel. Such the memory cells MC, eight in the example shown in FIG. 1, are serially connected to configure cell blocks MCB0, MCB1. Each cell block MCB0, MCB1 configures a ferroelectric memory (FeRAM) of the TC parallel unit serial connection type. FIG. 1 shows two cell blocks MCB0, MCB1 connected to a pair of bit lines BL, BBL.

The cell blocks MCB0, MCB1 are connected at one end N1 to the bit lines BL, BBL via block selection transistors BST0, BST1 and connected at the other end N2 to plate lines PL, BPL. The cell transistors Tr in the cell blocks MCB0, MCB1 have respective gates connected to word lines WL0-WL7.

The bit lines BL, BBL are connected to the sense amplifier circuit 2a (or 2b). The plate lines PL, BPL are connected to the plate-line drive circuit 3a (or 3b). The word lines WL0-WL7 are connected to the sub-row decoder circuit 4a (or 4b). The sub-row decoder circuits 4a, 4b are connected to the main row decoder circuit 5 through main block selection lines MBS0, MBS1.

The plate-line drive circuit 3a (or 3b) has a function of selectively driving the plate lines PL, BPL. The sub-row decoder circuit 4a (or 4b) has a function of selectively driving the word lines WL0-WL7. The main row decoder circuit 5 has a function of selectively driving the sub-row decoder circuits 4a, 4b with control signals fed through the main block selection lines MBS0, MBS1.

### (Operation of Semiconductor Device 100 According to First Embodiment)

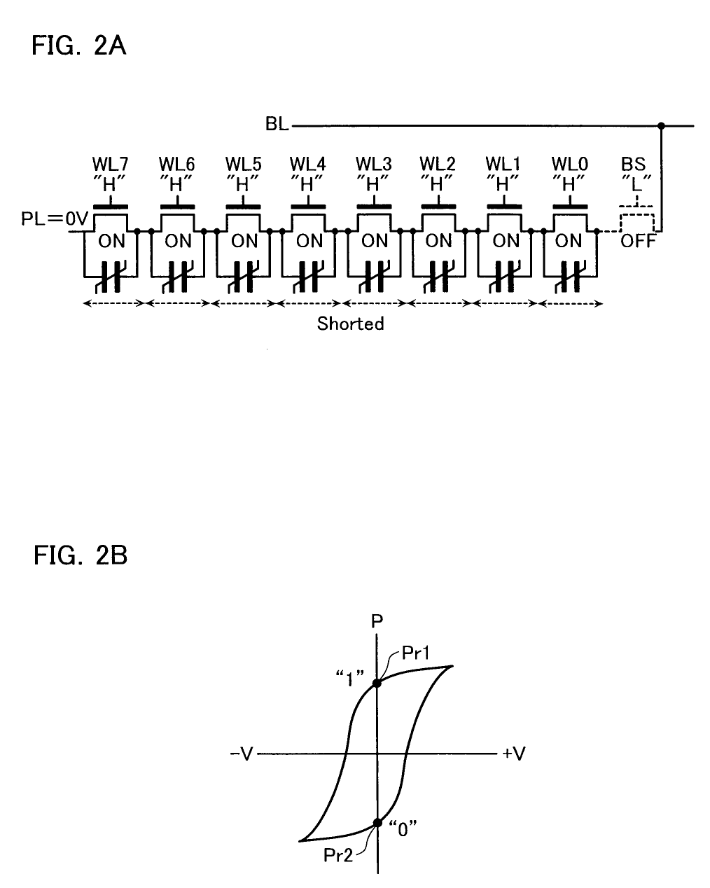

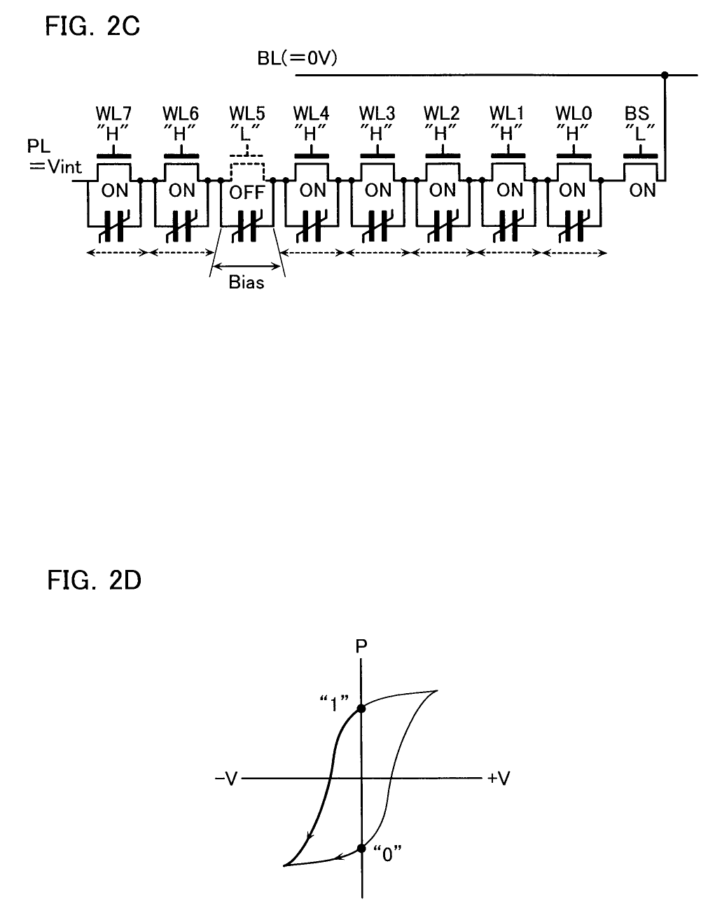

Referring next to FIGS. 2A-2D, operation of the semiconductor device 100 according to the first embodiment is described. By way of example, operation of the cell block MCB in the memory cell array 1a is described. FIGS. 2A and 2B show an overview of the semiconductor device 100 according to the first embodiment during standby while FIGS. 2C and 2D show an overview of the semiconductor device 100 according to the first embodiment during operation.

As shown in FIG. 2A, during standby, the sub-row decoder circuit 4a drives the word lines WL0-WL7 into the “H (high)” state. This drive turns on each transistor Tr. The sub-row decoder circuit 4a drives the block selection line BS into the “L (low)” state, which turns off the block selection transistor BST0. The plate-line drive circuit 3a brings the plate line PL into 0 V. These operations make the ferroelectric capacitor C in the memory cell MC shorted.

In the memory cell MC (FeRAM), when one word line WL is made “L” to apply a voltage to the ferroelectric capacitor for read, one of data “0”, “1” is inevitably associated with inversion of spontaneous polarization. Therefore, rewrite operation is required after read to invert the inverted spontaneous polarization once again with the read data. As shown in FIG. 2B, spontaneous polarization Pr1, Pr2 in the hysteresis characteristic of the ferroelectric capacitor may correspond to the stored states of data “1”, “0”.

Subsequently, as shown in FIG. 2C, during operation, the sub-row decoder circuit 4a drives the block selection line BS into the “H (high)” state, which turns on the block selection transistor BST0. The bit line BL is precharged to a certain potential (0V) by a precharge circuit, not shown, and then brought into the floating state. Subsequently, the plate-line drive circuit 3a elevates the voltage on the plate line PL to Vint. Then, the sub-row decoder circuit 4a drives a selected word line (WL5 in this example) into the “L (low)” state, which turns off only the transistor Tr connected to the word line WL5 and allows data read out of the parallel-connected ferroelectric capacitor C.

The above operation causes a variation in potential on the bit line BL, which varies in accordance with the amount of residual polarization of “1” data and the amount of residual polarization of “0” data as shown in FIG. 2D. The sense amplifier circuit 2a reads the difference between the signal quantities.

### (Structure of Memory Cell Array 1a in Semiconductor Device 100 According to First Embodiment)

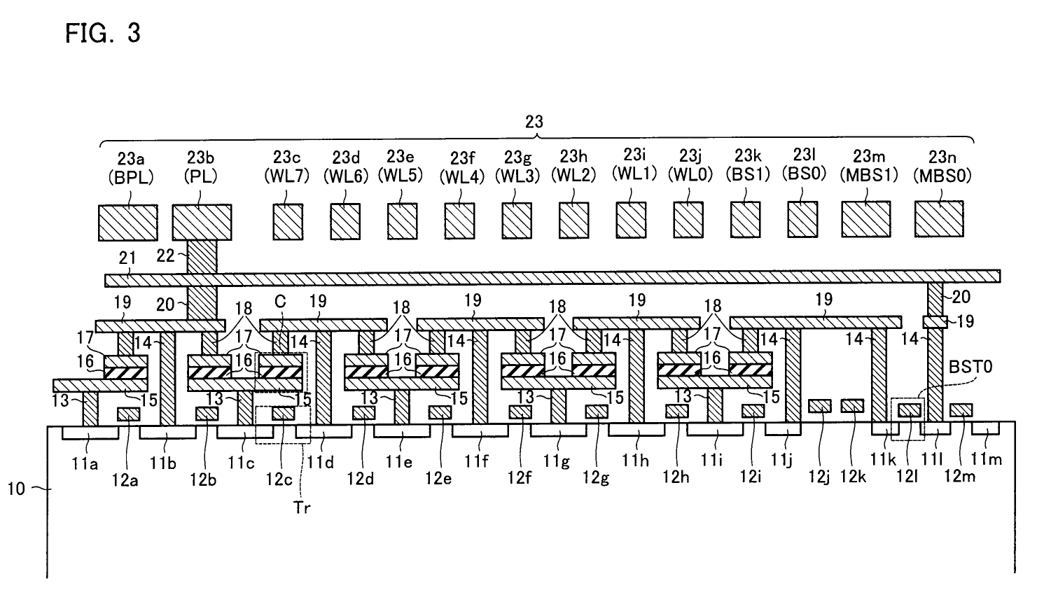

Referring next to FIG. 3, a structure of the memory cell array 1a in the semiconductor device 100 according to the first embodiment is described. FIG. 3 is a brief cross-sectional view of the major part of the cell block MCB0 in the memory cell array 1a. The configuration of the cell block MCB1 and the configuration of the cell blocks MCB0, MCB1 in the memory cell array 1b are almost similar to the configuration of the cell block MCB0 in the memory cell array 1a and accordingly omitted from the following description.

As shown in FIG. 3, the memory cell array 1a is configured with a stacked structure on a semiconductor substrate 10. The semiconductor substrate 10 has an upper surface, on which first source/drain layers 11a, 11c, 11e, 11g, 11i, second source/drain layers 11b, 11d, 11f, 11h, and third source/drain layers 11j-11m are formed to configure sources/drains of memory cell transistors Tr.

Between one of the first source/drain layers 11a, 11c, 11e, 11g, 11i and adjacent one of the second source/drain layers 11b, 11d, 11f, 11h, gate electrodes 12a-12i are each arranged, with a certain insulating layer (gate insulator 31 as described later) interposed. Between the third source/drain layers 11j, 11k, two gate electrodes 12j, 12k are arranged, with a certain insulating layer interposed. Between the third source/drain layers 11k-11m, gate electrodes 12l, 12m are arranged, with a certain insulating layer interposed. The gate electrodes 12j, 12k may be used as dummy gate electrodes.

On the first source/drain layers 11a, 11c, 11e, 11g, 11i, lower plug electrodes 13 are formed extending a first length upright. On the second source/drain layers 11b, 11d, 11f, 11h and on the third source/drain layers 11j-11m, line connection plug electrodes 14 are formed extending a second length upright (the second length>the first length). On the lower plug electrodes 13, lower plug electrodes 15 are formed. On the lower electrode 15, a ferroelectric film 16 and an upper electrode 17 are stacked at two locations.

On the upper electrode 17, an upper plug electrode 18 is formed extending upright to a height equal to the upper surface of the line connection plug electrode 14. The line connection plug electrode 14 and two upper plug electrodes 18 adjacent to the line connection plug electrode 14 are connected through a M1 line layer 19 extending formed almost in parallel with the surface of the semiconductor substrate 10.

On a specific M1 line layer 19, a M1 connection plug electrode 20 is formed. On an upper end of the M1 connection plug electrode 20, a M2 line layer 21 is formed spanning plural M1 line layers 19. On the M2 line layer 21 above the M1 connection plug electrode 20, a M2 line plug electrode 22 is formed.

Above the M2 line plug electrode 22, a M3 line layer 23 is formed. The M3 line layer 23 includes plural line layers. The M3 line layer 23 includes plate line layers 23a, 23b, word line layers 23c-23j, selection gate line layers 23k, 23l and main block selection line layers 23m, 23n. The plate line layers 23a, 23b serve as the above plate lines BPL, PL. The word line layers 23c-23j serve as the above word lines WL7-WL0. The selection gate line layers 23k, 23l serve as the above selection bit lines BS1, BS0. The main block selection line layers 23m, 23n serve as the above main block selection lines MBS1, MBS0. For example, the plate line layer 23b is connected to the upper surface of the M2 line plug electrode 22. The word line layers 23c-23j are connected to the gate electrodes 12b-12i. The selection gate line layer 23l is connected to the gate electrode 121. The selection gate line 23m is connected to the gate electrode provided in the cell block MCB1.

In a word, in the configuration shown in FIG. 3, the source/drain layers 11b-11j and the gate electrodes 12b-12i serve as the transistors Tr in the memory cells MC. The lower electrode 15, the ferroelectric film 16 and the upper electrode 17 serve as the ferroelectric capacitor C in the memory cell MC. In other words, the ferroelectric capacitor C (capacitor layer) includes the lower electrode 15, the ferroelectric film 16 and the upper electrode 17 stacked in turn. The source/drain layers 11k, 11l and the gate electrode 121 serve as the block selection transistor BST0.

### (Detailed Structure of Memory Cell MC in Semiconductor Device According to First Embodiment)

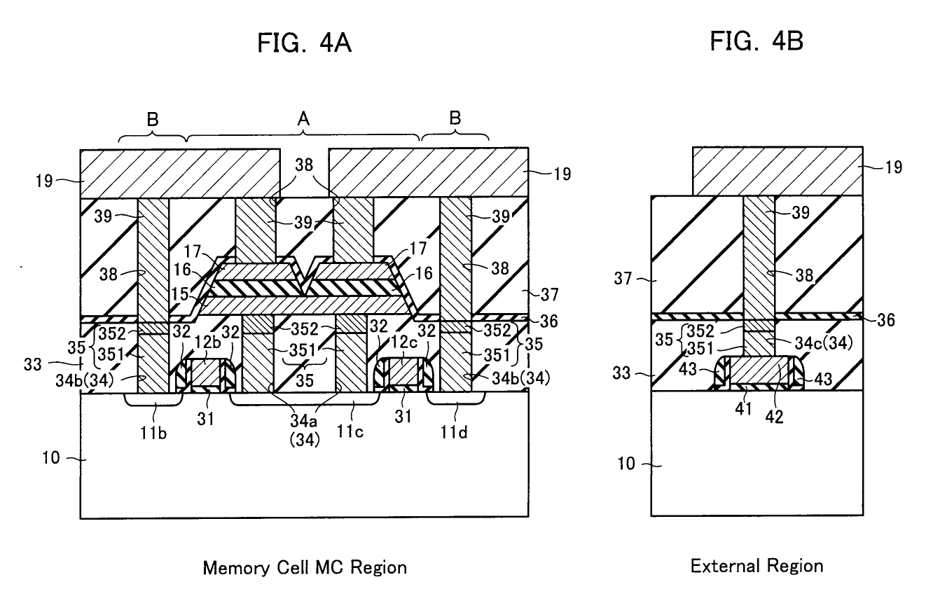

Referring next to FIGS. 4A and 4B, a detailed structure of the memory cell MC in the semiconductor device according to the first embodiment is described. FIGS. 4A and 4B show a memory cell MC region in which memory cells MC are formed, and an external region provided outside the memory cell arrays 1a, 1b. The external region is a region in which external circuits such as the sense amplifier circuits 2a, 2b, the plate-line drive circuits 3a, 3b, the sub-row decoder circuits 4a, 4b, and the main row decoder circuit 5 described above are formed.

The memory cell MC region is described first. The memory cells MC are formed on the semiconductor substrate 10 as shown in FIG. 4A similar to the configuration described above. On the upper surface of the semiconductor substrate 10, the first source/drain layer 11c and the second source/drain layers 11b, 11d at both sides are selectively formed. The first source/drain layer 11c locates in a first region A (the central portion of the memory cell MC region shown in FIG. 3). The second source/drain layers 11b, 11d locate in a second region B (both ends of the memory cell MC region shown in FIG. 3) different from the first region A. FIG. 4A shows only the structure on the second source/drain layers 11b, 11d with the first source/drain layer 11c located at the center. A similar structure to that in FIG. 4A is also formed on other first and second source/drain layers shown in FIG. 3.

On the semiconductor substrate 10 between the first source/drain layer 11c and the second source/drain layers 11b, 11d, a gate insulator 31 is formed. On the gate insulator 31, the above gate electrodes 12b, 12c are formed. On the sides of these gate insulator 31 and gate electrodes 12b, 12c, a sidewall insulator 32 is formed.

On the semiconductor substrate 10, a first insulator 33 is formed covering the source/drain layers 11b-11d, the gate electrodes 12b, 12c and the sidewall insulator 32. The first insulator 33 has a first thickness in the first region A and a second thickness different from the first thickness in the second region B (the second thickness<the first thickness).

The first insulator 33 includes a lower contact hole 34 formed therethrough from the upper surface to the lower surface. The lower contact hole 34 comprises a first lower contact hole 34a provided on the first source/drain layer 11c in the first region A, and a second lower contact hole 34b provided on the source/drain layers 11b, 11d in the second region B.

In the lower contact hole 34, a first plug electrode 35 is formed. The first plug electrode 35 comprises a plug conduction layer 351 formed from the surface of the substrate 10 to a certain height. The plug conduction layer 351 is composed of Ti/TiN/W (the barrier metal (Ti/TiN) is not shown). The first plug electrode 35 further comprises a plug barrier layer 352 formed from above the plug conduction layer 351 up to the upper surface of the first insulating layer 33. In other words, the plug barrier layer 352 is formed from the upper surface of the first insulating layer 33 to a certain depth. The plug barrier layer 352 is formed with a first thickness in the first lower contact hole 34a (the first region A) and with a second thickness in the second lower contact hole 34b (the second region B) (the second thickness<the first thickness).

The plug barrier layer 352 is composed of a material having a higher etching selection ratio than the lower electrode 15. The plug barrier layer 352 may be composed of TiAlₓN_{y}, WₓN_{y}, or TiₓN_{y} (x, y=1-99).

On the upper surface of the first plug electrode 35 in the first region A, the above-described lower electrode 15 is formed. On the upper surface of the lower electrode 15, the ferroelectric films 16, 16 and the upper electrodes 17, 17 are formed at each two locations. The ferroelectric films 16, 16 and the upper electrodes 17, 17 are formed mesa-shaped in section. In an example, the lower electrode 15 is composed of either Ir (120 nm) or Ti (2.5 nm)/Ir (120 nm). The ferroelectric film 16 is composed of Pb(ZrₓTi₁₋ₓ)O₃ (100 nm). The upper electrode 17 is composed of SrRuO₃ (10 nm)/IrO₂ (70 nm).

A hydrogen protection film 36 is formed on the upper surface of the first insulating layer 33, the side of the lower electrode 15, the side of the ferroelectric film 16, and the side and the upper surface of the upper electrode 17. The hydrogen protection film 36 may include a silicon oxide film (SiOₓ film such as a SiO₂ film), an aluminum oxide film (Alₓ film such as an Al₂O₃ film), a zirconium oxide film (ZrOₓ film such as a ZrO₂ film), and a silicon nitride film (SiₓN_{y} film such as a Si₃N₄ film). Alternatively, the hydrogen protection film 36 may be composed of a stacked film, which includes a silicon oxide film, an aluminum oxide film, a zirconium oxide film and a silicon nitride film in combination. The hydrogen protection film 36 is formed with a thickness of, for example, 100 nm.

A second insulating layer 37 is formed on the upper surface of the hydrogen protection film 36. An upper contact hole 38 is formed through the second insulating layer 37 and the hydrogen protection film 36. The upper contact hole 38 is formed above the lower contact hole 34. A second plug electrode 39 is formed inside the upper contact hole 38. In a word, the second plug electrode 39 is formed above the capacitor layer (denoted with the reference numerals 15, 16, 17) in the first region A and above the first plug electrode 35 in the first region B. The second plug electrode 39 is composed of, for example, aluminum (Al).

On the second plug electrode 39, the above-described M1 line layer 19 is formed.

The first plug electrode 35 in the first region A described in FIG. 4A serves as the lower plug electrode 13 described in FIG. 3. The first plug electrode 35 in the second region B and the second plug electrode 39 in the second region B serve as the line connection plug electrode 14. The second plug electrode 39 in the first region A serves as the upper plug electrode 18.

Subsequently, the external region in the semiconductor device 100 is described. In the external region, a gate electrode 42 is formed on the semiconductor substrate 10 with a gate insulator 41 interposed as shown in FIG. 4B. On the sides of the gate insulator 41 and the gate electrode 42, a sidewall insulator 43 is formed.

On the semiconductor substrate 10, the first insulating layer 33 is formed covering the gate insulator 41 and the sidewall insulator 43. From the upper surface of the first insulating layer 33 to a depth reaching the upper surface of the gate electrode 42, a third lower contact hole 34c is formed. Inside the third lower contact hole 34c, the first plug electrode 35 is formed, like the second region B in the memory cell region MC. On the upper surfaces of the first insulating layer 33 and the first plug electrode 35, the hydrogen protection film 36 and the second insulating layer 37 are stacked, like the second region B in the memory cell region MC. Through the hydrogen protection film 36 and the second insulating layer 37, the upper contact hole 38 is formed, and inside the upper contact hole 38, the second plug electrode 39 is formed. The M1 line layer 19 is formed on the second plug electrode 39.

### (First Method of Manufacturing Semiconductor Device 100 According to First Embodiment)

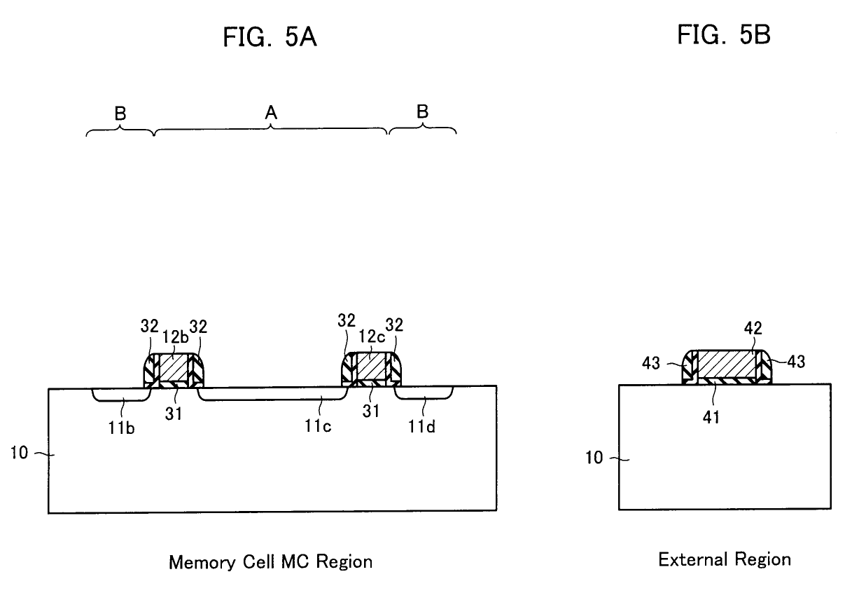

Referring next to FIGS. 5A and 5B through FIGS. 16A and 16B, the first process steps of manufacturing the semiconductor device 100 according to the first embodiment are described. FIGS. 5A and 5B through FIGS. 16A and 16B show the first process steps of manufacturing the semiconductor device 100 according to the first embodiment. FIGS. 5A-16B show a memory cell MC region and 5B-16B show an external region.

First, as shown in FIGS. 5A and 5B, the layers serving as the transistor Tr (the gate insulator 31, the gate electrode 12, and the sidewall insulator 32) in the memory cell MC region are formed on the semiconductor substrate 10. In addition, the layers serving as the transistor (the gate insulator 41, the gate electrode 42, and the sidewall insulator 43) in the external region are formed on the semiconductor substrate 10.

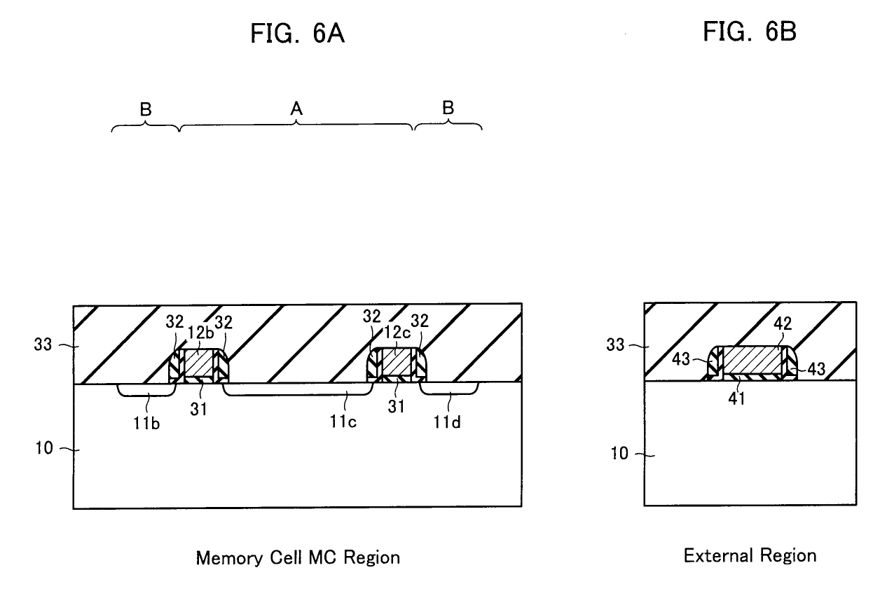

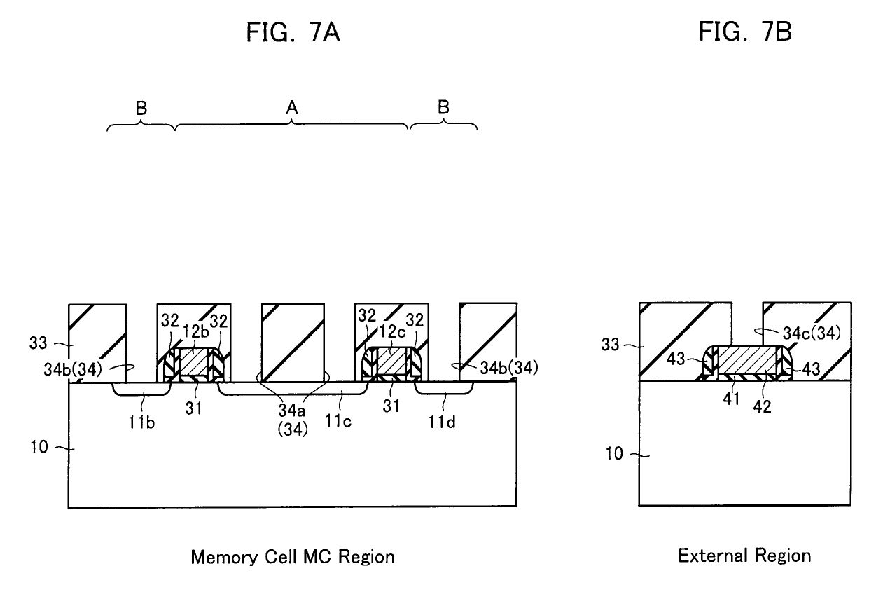

Subsequently, as shown in FIGS. 6A and 6B, the first insulating layer 33 is deposited over the transistors in the memory cell MC region and the external region described in FIGS. 5A and 5B. Thereafter, as shown in FIGS. 7A and 7B, etching is applied to remove the first insulating layer 33 to form the lower contact hole 34 through the first insulating layer 33.

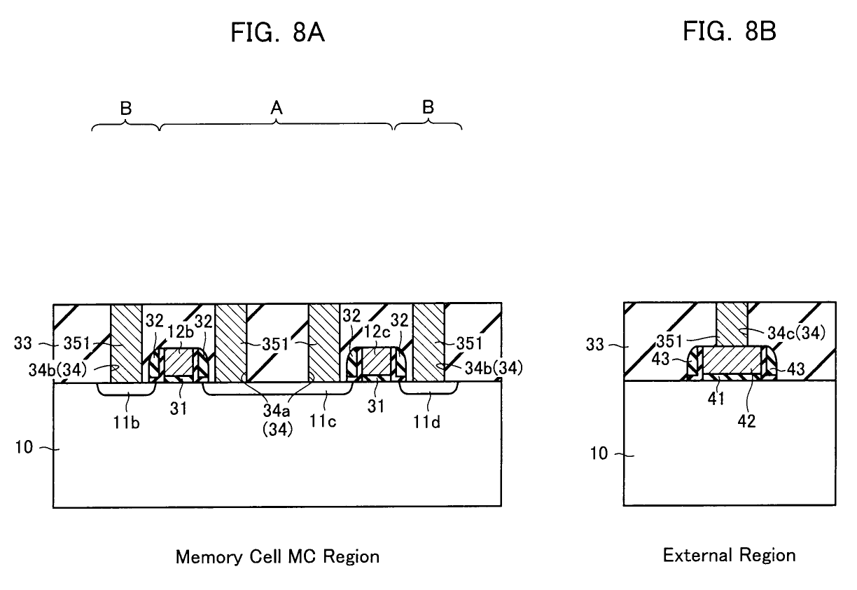

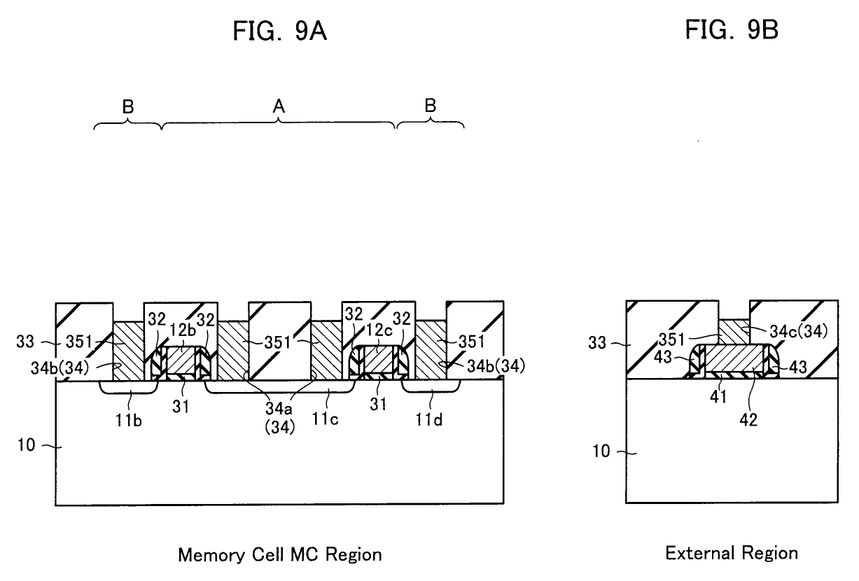

Next, as shown in FIGS. 8A and 8B, a plug conduction layer 351 is deposited inside the lower contact hole 34. Subsequently, as shown in FIGS. 9A and 9B, a reactive ion etching (RIE) process, a chemical dry etching (CDE) process, or a wet processing procedure is used to etch back the upper portion of the plug conduction layer 351. For example, the etched-back depth in the upper portion of the first plug electrode 35 is equal to 50 nm. In the RIE process or the CDE process, a chlorine-based gas is used to achieve a higher etching selection ratio than the first insulating layer 33. In the wet processing procedure, a solution incapable of etching the silicon oxide (SiO₂) is used (other than hydrofluoric acid (HF)-based solutions).

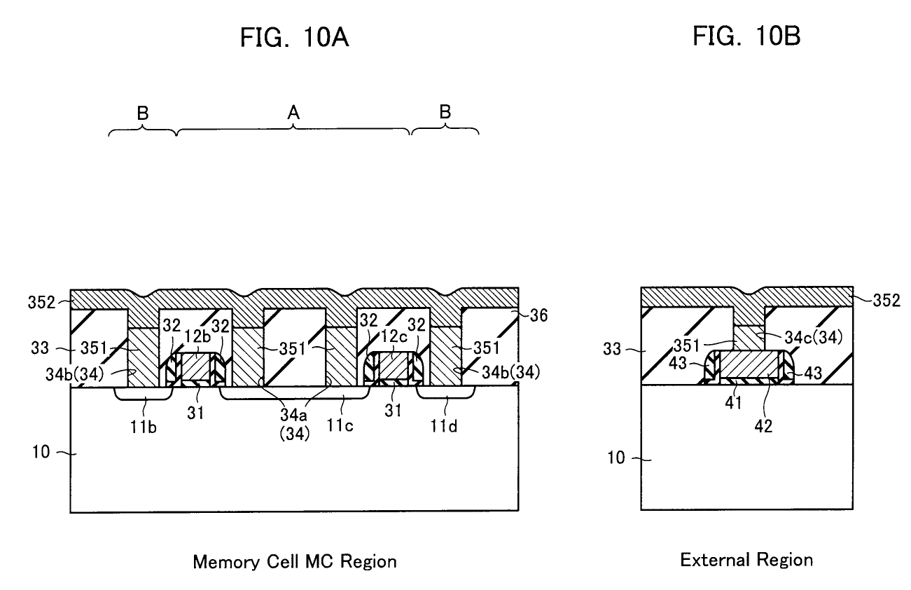

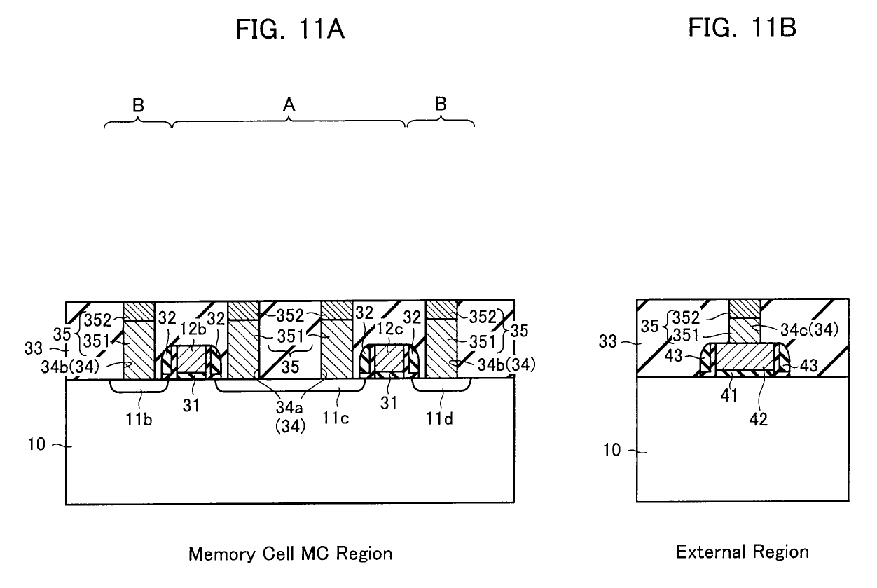

Then, as shown in FIGS. 10A and 10B, a CVD process or a spattering process is used to deposit a plug barrier layer 352 over the plug conduction layer 351 and the first insulating layer 33. Subsequently, as shown in FIGS. 11A and 11B, a chemical mechanical polishing (CMP) process is applied such that the upper surface of the plug barrier layer 352 reaches a height equal to the surface of the first insulating layer 33.

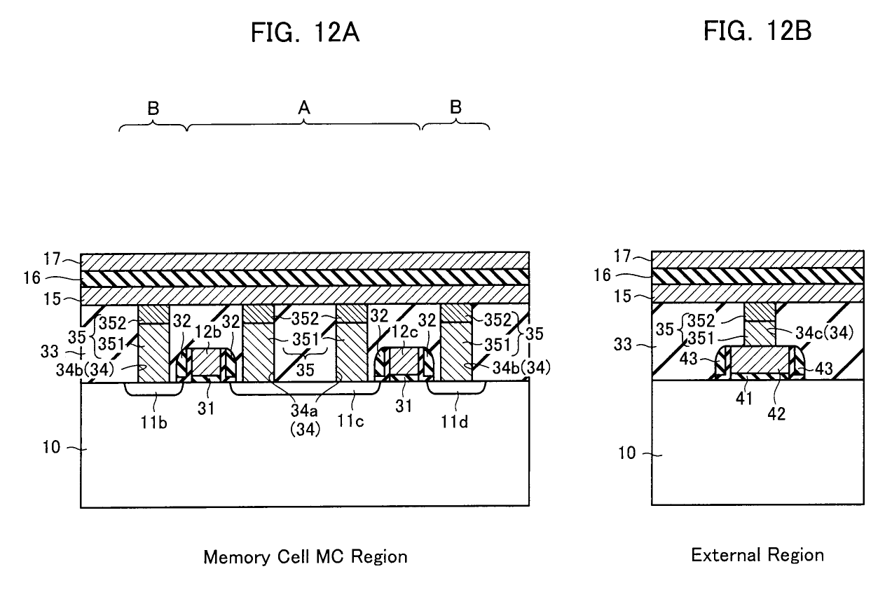

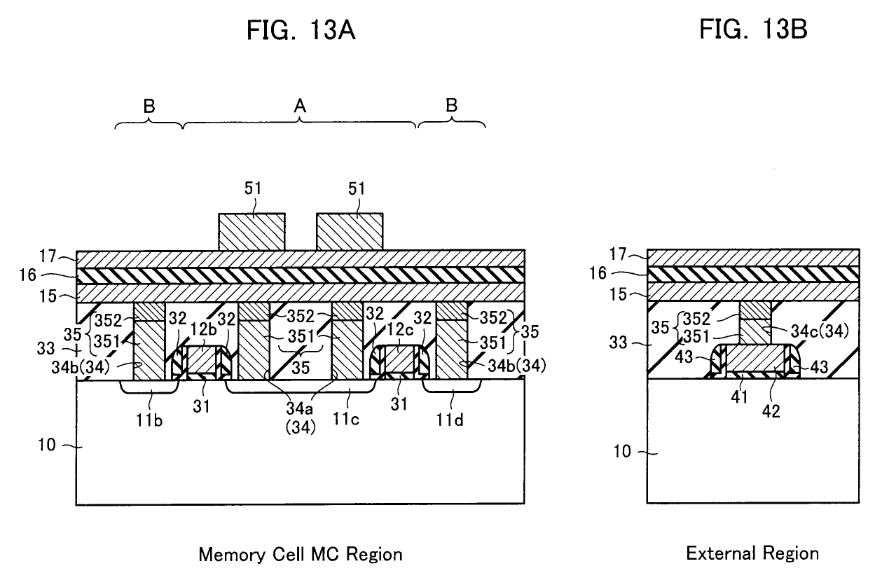

Next, as shown in FIGS. 12A and 12B, the lower electrode 15, the ferroelectric layer 16 and the upper electrode 17 are stacked over the upper surface of the first insulating layer 33 and the upper surface of the plug barrier layer 352. Subsequently, as shown in FIGS. 13A and 13B, on the upper electrode 17 located above the first source/drain layer 11c, a hard mask 51 is formed. The hard mask 51 may be suitably composed of a SiO₂ film when a high-temperature RIE process at 300° C. or higher is used in the process described in detail below. Other structures of the hard mask 51 may be composed of a silicon oxide film (SiOₓ film such as a SiO₂ film), an aluminum oxide film (AlₓO_{y} film such as an Al₂O₃ film), a silicon aluminum oxide film (SiAlₓO_{y} film such as an SiAlO film), a zirconium oxide film (ZrOₓ film such as a ZrO₂ film), a silicon nitride film (SiₓN_{y} film such as a Si₃N₄ film), a titanium aluminum nitride film (TiAlₓN_{y} film such as an TiAl_{0.5}N_{0.5} film), or a stacked film including the above films in combination (which are similarly applicable to the following embodiments).

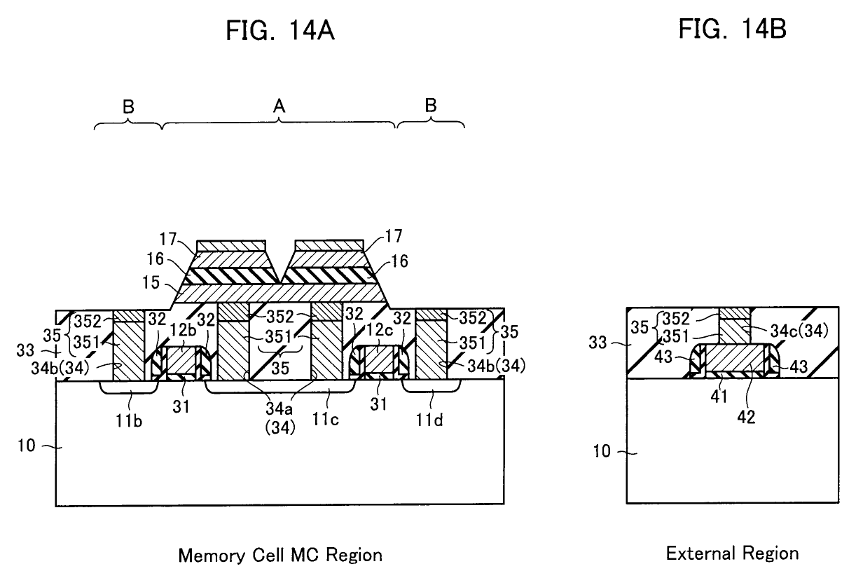

Next, as shown in FIGS. 14A and 14B, an etching by high-temperature RIE is applied from above the hard mask 51 to remove the lower electrode 15, the ferroelectric film 16 and the upper electrode 17 from the region in which the hard mask 51 is not formed. In a region between adjacent portions of the hard mask 51, the ferroelectric film 16 and the upper electrode 17 are removed therefrom, leaving the lower electrode 15. In a region (the second region B) other than the hard mask 51 and the region between adjacent portions of the hard mask 51, the upper surface of the first insulating layer 33 is removed down to a certain depth. The hard mask 51, the ferroelectric film 16 and the upper electrode 17 left serve as the capacitor layer. Thereafter, the hard mask 51 left after processing is removed in the present process step although the hard mask 51 may be left on the upper electrode 17.

In the step shown in FIGS. 14A and 14B, the plug barrier layer 352 is composed of a material having a higher etching selection ratio than the lower electrode 15. Therefore, the plug barrier layer 352 suppresses over-etching of the surface of the first plug electrode 35 around the lower electrode 15.

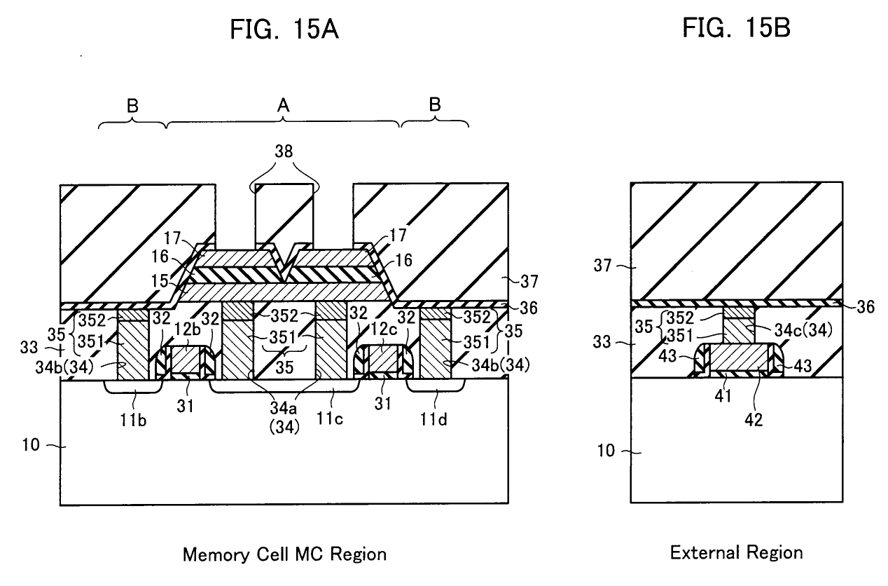

Next, as shown in FIGS. 15A and 15B, the hydrogen protection film 36 is deposited on the surfaces (denoted with the reference numerals 33, 352, 15, 16, 17). Subsequently, the second insulating layer 37 is deposited on the hydrogen protection film 36. Then, the upper contact hole 38 is formed through the second insulating layer 37 and the hydrogen protection film 36 such that the upper surface of the upper electrode 17 is exposed. In opening the upper contact hole 38, a high-temperature chlorine-based gas is used.

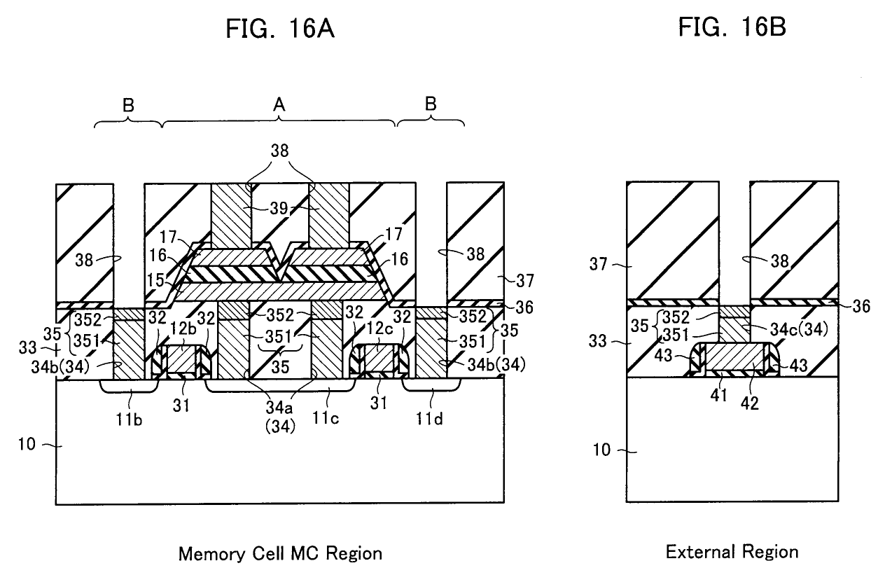

Next, as shown in FIGS. 16A and 16B, tungsten (W) or the like is deposited inside the upper contact hole 38 on the upper electrode 17 to form the second plug electrode 39. Thereafter, an etching is applied to remove the second insulating layer 37 and the hydrogen protection film 36 from above the second source/drain layers 11b, 11d (the second region B) to form the upper contact hole 38.

Subsequent to the state of FIGS. 16A and 16B, the second plug electrodes 39 are formed inside the upper contact holes 38 provided above the second source/drain layers 11b, 11d. Then, the M1 line layer 19 is formed over the second plug electrode 39 and the second insulating layer 37 to bring the device into the state shown in FIGS. 4A and 4B.

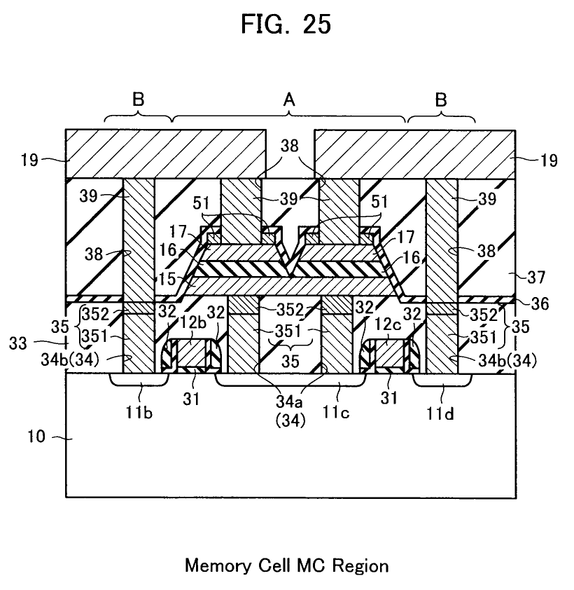

If the hard mask 51 is not removed but left on the upper electrode 17 in the step shown in FIGS. 14A and 14B, the memory cell MC region in the semiconductor device becomes as shown in a cross-sectional view of FIG. 25.

### (Second Method of Manufacturing Semiconductor Device According to First Embodiment)

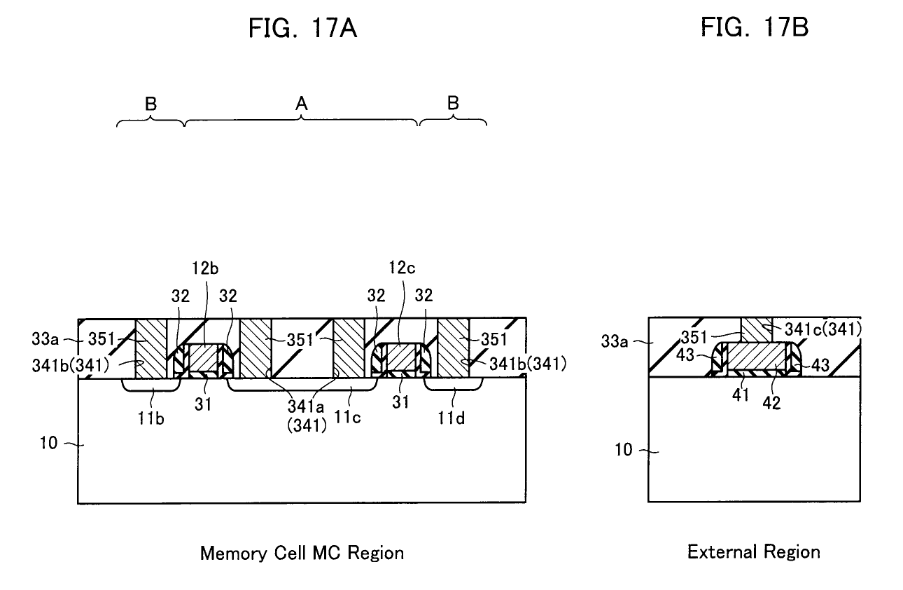

Referring next to FIGS. 17A and 17B through FIGS. 21A and 21B, the second process steps of manufacturing the semiconductor device 100 according to the first embodiment are described. FIGS. 17A and 17B through FIGS. 21A and 21B show the second process steps of manufacturing the semiconductor device 100 according to the first embodiment. FIGS. 17A-21A show a memory cell MC region and 17B-21B show an external region.

In the second process steps, first, a lower first insulating layer 33a with a thickness thinner than the first insulating layer 33 is formed on the semiconductor substrate 10. Thereafter, steps almost similar to those of FIGS. 5-8 in the first process steps are executed to establish the state shown in FIGS. 17A and 17B. Namely, first holes 341 (341a, 341b, 341c) are formed through the lower first insulating layer 33a in the thickness direction.

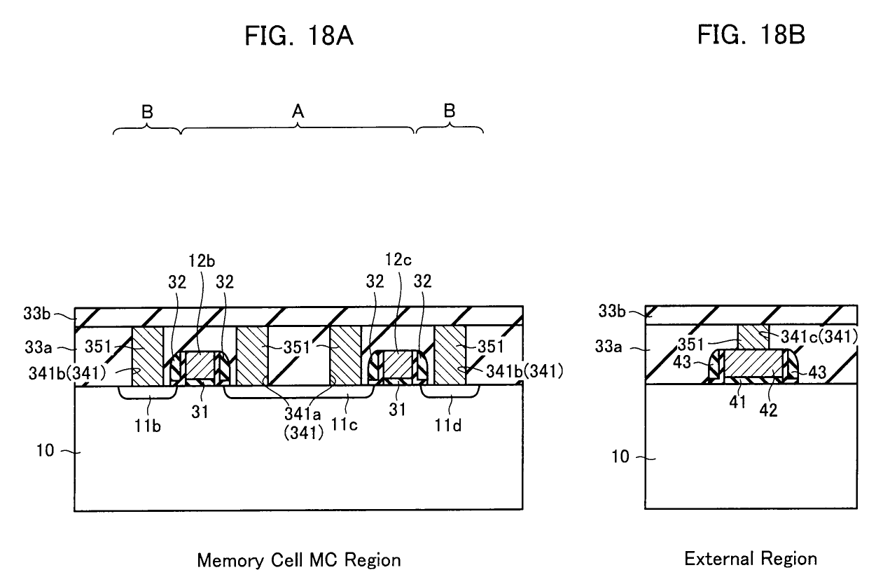

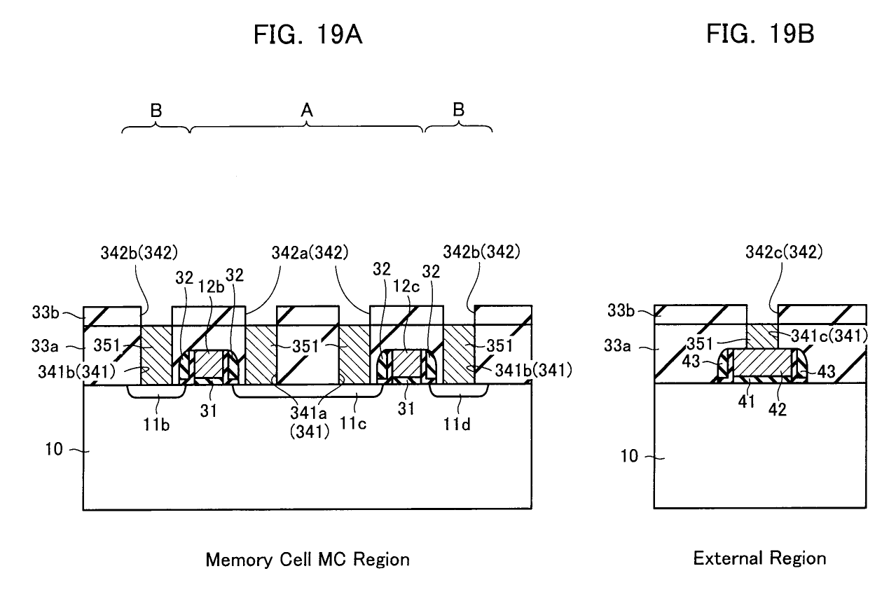

Next, as shown in FIGS. 18A and 18B, an upper first insulating layer 33b is deposited over the lower first insulating layer 33a and the plug conduction layer 351. The thickness of the lower first insulating layer 33a plus the thickness of the upper first insulating layer 33b is equal to the thickness of the first insulating layer 33. Subsequently, as shown in FIGS. 19A and 19B, second holes 342 (342a, 342b, 342c) are formed through the upper first insulating layer 33b above the plug conduction layer 351. In a word, the first hole 341 and the second hole 342 are combined to form the lower contact hole 34.

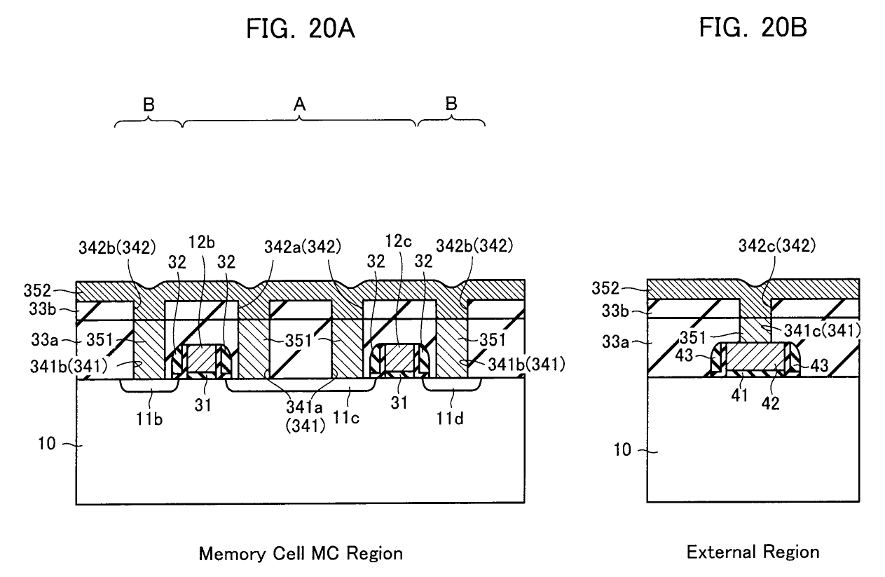

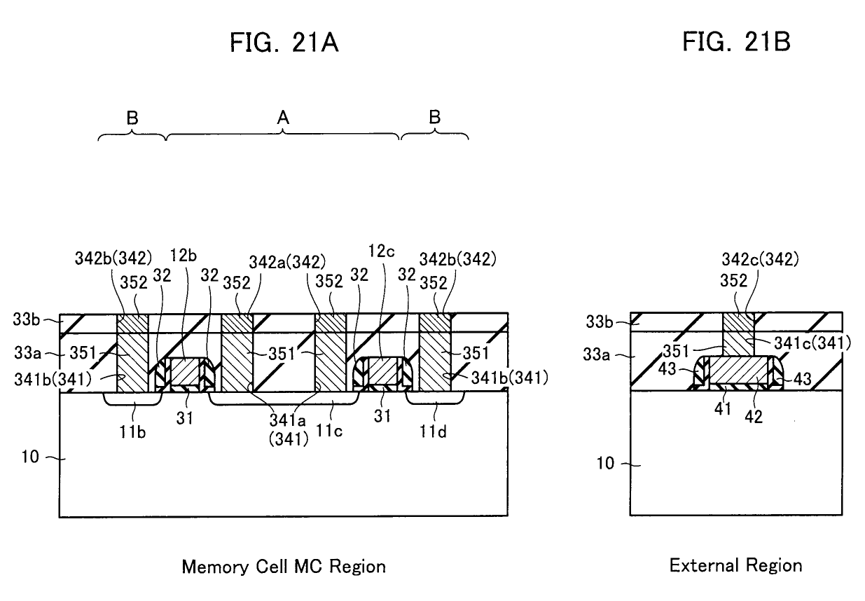

Next, as shown in FIGS. 20A and 20B, a CVD process or a spattering process is used to deposit a plug barrier layer 352. Subsequently, as shown in FIGS. 21A and 21B, a CMP process is applied such that the upper surface of the plug barrier layer 352 reaches a height equal to the surface of the upper first insulating layer 33b. The steps subsequent to that of FIGS. 21A and 21B are executed almost similar to those in FIGS. 12A and 12B through FIGS. 16A and 16B.

The semiconductor device 100 according to the first embodiment includes the first plug electrode 35 as above. The first plug electrode 35 includes the plug barrier layer 352, which is formed from the upper surface of the first plug electrode 35 down to a certain depth and has a higher etching selection ratio than the lower electrode 15. In a word, the plug barrier layer 352 can suppress over-etching of the surface of the first plug electrode 35 around the lower electrode 15 on formation of the capacitor shown in FIG. 14A. Therefore, it is possible to improve the coverage of the hydrogen protection film 36 formed in the step shown in FIGS. 15A and 15B and improve the reliability of the semiconductor device 100. It is also possible to form the memory cell MC region and the external region at the same time through the above process steps. In a word, it is possible to improve the yield and manufacture the semiconductor device 100 at low costs.

### Second Embodiment

(Detailed Structure of Memory Cell in Semiconductor Device according to Second Embodiment)

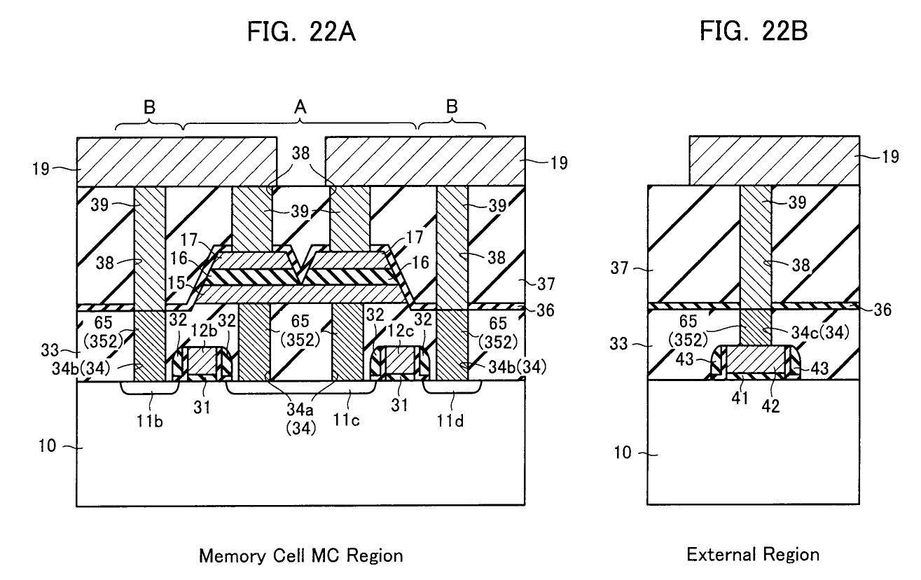

Referring next to FIGS. 22A and 22B, a detailed structure of a memory cell MC in a semiconductor device according to a second embodiment is described. FIGS. 22A and 22B show a memory cell MC region in which memory cells MC in the semiconductor device according to the second embodiment are formed, and an external region. The same elements in the second embodiment as those in the first embodiment are denoted with the same reference numerals and omitted from the following description.

As shown in FIGS. 22A and 22B, the semiconductor device according to the second embodiment includes a first plug electrode 65 formed inside the lower contact hole 34 only with the plug barrier layer 352 deposited therein, in place of the first plug electrode 35 of the first embodiment. In other words, the plug barrier layer 352 is formed from the surface of the substrate 10 up to the upper surface of the first insulating layer 33. In the semiconductor device according to the second embodiment, the configuration of the first plug electrode 65 differs from the configuration of the first embodiment.

### (Method of Manufacturing Semiconductor Device According to Second Embodiment)

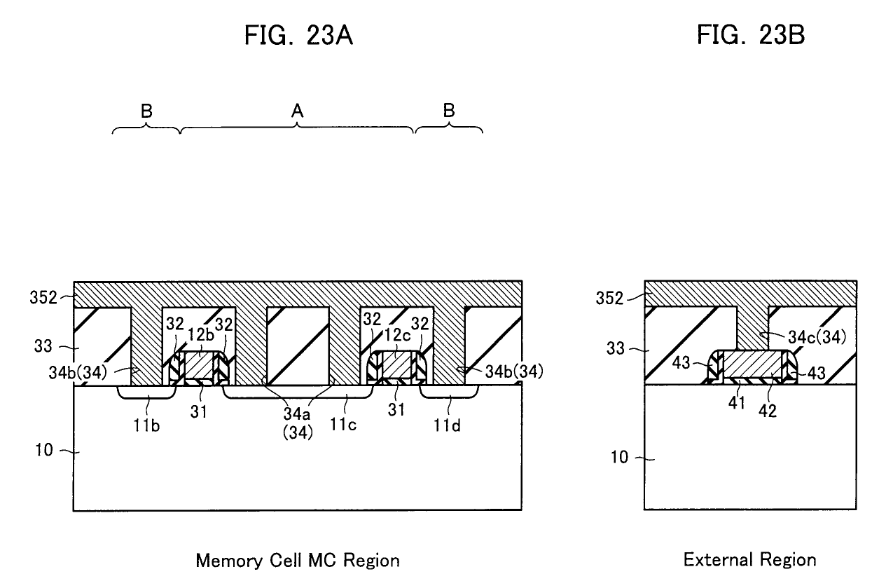

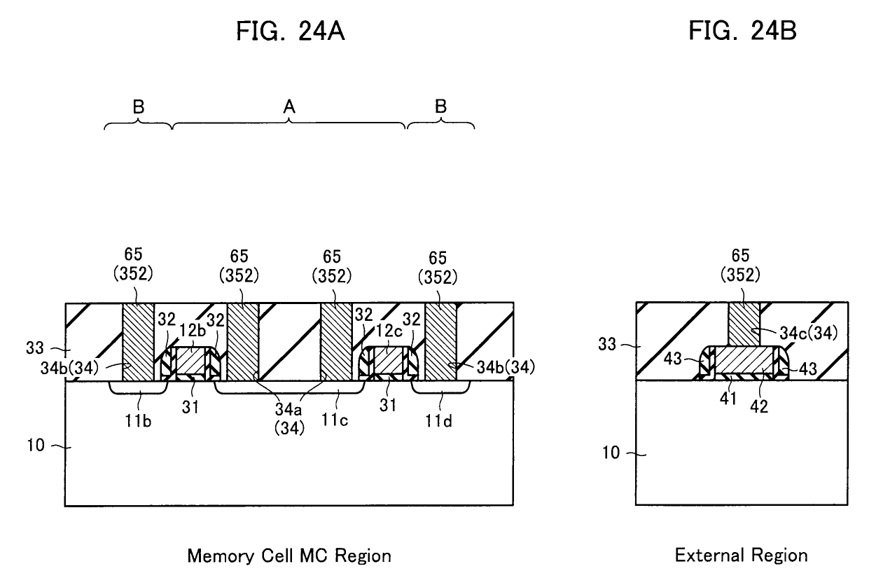

Referring next to FIGS. 23A, 23B, 24A and 24B, the process steps of manufacturing the semiconductor device according to the second embodiment are described. FIGS. 23A, 23B, 24A and 24B show the process steps of manufacturing the semiconductor device according to the second embodiment. FIGS. 23A and 24A show a memory cell MC region and FIGS. 23B and 24B show an external region.

In the process steps of manufacturing the semiconductor device according to the second embodiment, process steps similar to the steps of FIGS. 5A and 5B through FIGS. 7A and 7B in the first process steps of the first embodiment are executed first. Subsequent to the step of FIGS. 7A and 7B, the plug barrier layer 352 is deposited inside the lower contact hole 34 as shown in FIGS. 23A and 23B. Subsequently, a CMP process is applied such that the upper surface of the plug barrier layer 352 reaches a height equal to the surface of the first insulating layer 33 as shown in FIGS. 24A and 24B. Subsequent to the step of FIGS. 24A and 24B, steps almost similar to those of FIGS. 12A and 12B through FIGS. 16A and 16B are executed to establish the state shown in FIGS. 22A and 22B.

The semiconductor device according to the second embodiment includes the first plug electrode 65 as above. The first plug electrode 65 includes the plug barrier layer 352, which is formed from the upper surface of the first plug electrode 35 to the depth of the lower contact hole 34 and has a higher etching selection ratio than the lower electrode 15. Therefore, the semiconductor device according to the second embodiment can exert the same effect as that of the first embodiment.

The embodiments of the invention have been described above though the present invention is not limited to these embodiments but rather can be given various modifications, additions and so forth without departing from the scope and spirit of the invention. The semiconductor devices according to the first and second embodiments are FeRAMs of the TC parallel unit serial connection type though they may be used in configuring FeRAMs of the 1T type (Transistor type), FeRAMs of the 1T1C type (Capacitor type), or FeRAMs of the 2T2C type.

What is claimed is:

1. A semiconductor device, comprising:
a substrate;
an insulating layer formed over said substrate;
a contact hole formed through said insulating layer;
a plurality of first plug electrodes each formed inside said contact hole up to the surface of said insulating layer;
a capacitor layer formed on said first plug electrode in a first region; and
a second plug electrode formed on said first plug electrode in a second region different from said first region,
said capacitor layer including
a lower electrode, a ferroelectric film, and an upper electrode stacked in turn,
said first plug electrode including
a plug conduction layer formed from the surface of said substrate, and
a plug barrier layer formed from above said plug conduction layer up to an upper surface of said insulating layer, said plug barrier layer having a higher etching selection ratio than said lower electrode.

2. The semiconductor device according to claim 1, wherein said insulating layer is formed in said first region with a first thickness and in said second region with a second thickness different from said first thickness.

3. The semiconductor device according to claim 1, wherein said plug barrier layer is formed in said first region with a first thickness and in said second region with a second thickness different from said first thickness.

4. The semiconductor device according to claim 2, wherein said plug barrier layer is formed in said first region with a first thickness and in said second region with a second thickness different from said first thickness.

5. The semiconductor device according to claim 1, wherein said plug barrier layer is composed of any one of TiAlₓN_{y}, WₓN_{y}, and TiₓN_{y} (x, y=1-99).

6. The semiconductor device according to claim 1, wherein said lower electrode is composed of Ir or Ti/Ir.

7. The semiconductor device according to claim 1, further comprising a hydrogen protection film formed on upper surfaces of said insulating layer, said lower electrode, said ferroelectric film and said upper electrode.

8. The semiconductor device according to claim 1, further comprising a hard mask formed on an upper surface of said upper electrode.

9. The semiconductor device according to claim 1, further comprising a transistor formed on said substrate and having a first and a second source/drain layer,
wherein said first source/drain layer is connected to said lower electrode via said first plug electrode in said first region,
wherein said second source/drain layer is connected to said upper electrode via said first plug electrode and said second plug electrode in said second region and via said second plug electrode in said first region.

10. A semiconductor device, comprising:
a substrate;
an insulating layer formed over said substrate;
a contact hole formed through said insulating layer;
a plurality of first plug electrodes each formed inside said contact hole up to the surface of said insulating layer;
a capacitor layer formed on said first plug electrode in a first region; and
a second plug electrode formed on said first plug electrode in a second region different from said first region,
said capacitor layer including
a lower electrode, a ferroelectric film, and an upper electrode stacked in turn,
said first plug electrode including
a plug barrier layer formed from the surface of said substrate up to an upper surface of said insulating layer, said plug barrier layer having a higher etching selection ratio than said lower electrode.

11. The semiconductor device according to claim 10, wherein said insulating layer is formed in said first region with a first thickness and in said second region with a second thickness different from said first thickness.

12. The semiconductor device according to claim 10, wherein said plug barrier layer is formed in said first region with a first thickness and in said second region with a second thickness different from said first thickness.

13. The semiconductor device according to claim 11, wherein said plug barrier layer is formed in said first region with a first thickness and in said second region with a second thickness different from said first thickness.

14. The semiconductor device according to claim 10, further comprising a hydrogen protection film formed on upper surfaces of said insulating layer, said lower electrode, said ferroelectric film and said upper electrode.

15. The semiconductor device according to claim 10, further comprising a hard mask formed on an upper surface of said upper electrode.

16. The semiconductor device according to claim 10, further comprising a transistor formed on said substrate and having a first and a second source/drain layer,
wherein said first source/drain layer is connected to said lower electrode via said first plug electrode in said first region,
wherein said second source/drain layer is connected to said upper electrode via said first plug electrode and said second plug electrode in said second region and via said second plug electrode in said first region.

17. A method of manufacturing semiconductor devices, comprising:
depositing an insulating layer over a substrate;
forming a contact hole through said insulating layer;
forming a first plug electrode inside said contact hole up to the surface of said insulating layer;
forming a capacitor layer on said first plug electrode in a first region by stacking a lower electrode, a ferroelectric film, and an upper electrode; and
forming a second plug electrode on said first plug electrode in a second region different from said first region,
said method further comprising; for forming said first plug electrode,
forming a plug conduction layer from the surface of said substrate, and
forming a barrier layer from above said plug conduction layer up to an upper surface of said insulating layer, said barrier layer having a higher etching selection ratio than said lower electrode, thereby configuring said first plug electrode with said plug conduction layer and said barrier layer.

18. The method of manufacturing semiconductor devices according to claim 17, wherein
said lower electrode is composed of Ir or Ti/Ir,
said barrier layer in said first plug electrode is composed of any one of TiAlₓN_{y}, WₓN_{y}, and TiₓN_{y} (x, y=1-99).

19. The method of manufacturing semiconductor devices according to claim 17, wherein forming said capacitor layer including
forming a hard mask on the surface of said upper electrode, and
removing said lower electrode, said ferroelectric film and said upper electrode from a region in which said hard mask is not formed, thereby forming said capacitor layer.

20. The method of manufacturing semiconductor devices according to claim 17, further depositing a hydrogen protection film on the surfaces of said insulating layer and said capacitor layer, after forming said capacitor layer.
